(19) United States
(12) Patent Application Publication
(10) Pub. No.: US 2007/0111353 A1
(43) Pub. Date: May 17, 2007

(54) Hybrid microfluidic chip and method for manufacturing same

(75) Inventors: John McCaskill, Bonn (DE); Thomas Maeke, Bonn (DE); Uwe Tangen, Koenigswinter (DE); Patrick Wagler, Boppard (DE); Steffen Chemnitz, Siegen (DE); Martina Juenger, Rheinbreitbach (DE)

Correspondence Address: SHUMAKER & SIEFFERT, P. A., 1625 RADIO DRIVE, SUITE 300, WOODBURY, MN, 55125, US

(73) Assignee: Protolife Sr.l, Venezia (IT)

(21) Appl. No.: 10/582,008

(22) PCT Filed: Nov. 25, 2004
(86) PCT No.: PCT/EP04/13361

§ 371 Date: Nov. 20, 2006

(30) Foreign Application Priority Data
Dec. 8, 2003 (EP) 03028065.5

(51) Int. Cl. H01L 21/00; H01L 23/34

(52) U.S. Cl. 438/42; 257/712

(57) ABSTRACT

The invention concerns an electrically active hybrid biochip equipped with a printed circuit wafer provided with a polymer support, whereof one surface at least comprises an electrically conductive layer with several electrodes. On the said electrically conductive layer are applied one or more acrylic polymer or resist layers of epoxy resin, phenol resin, silicone resin or fluorinated polymer, the said layers being structured by photolithography or by electronic beam and applied while leaving exposed at least one of the electrodes. The microfluidic system further comprises a material layer for microchannels with an outer surface wherein are arranged recesses forming microchannels, the said material layer comprising PDMS (polydimethylsiloxane, SYLGARD®, DOW Corning), other organic siloxanes and their polymerization products, silicones, polyacrylates (such as PMMA) and/or elastomers with functional groups containing oxygen and/or nitrogen (for example, polysulphone, polyimide, polycarbonate and/or polyacrylnitrile). The outer surface comprising recesses of the material layer for microchannels is in contact with the photosensitive resist layer of the printed circuit wafer such that the two electrodes are aligned with one of the recesses arranged in the lithography-structured resist layer, the outer surface of the material layer being in sealed fluid communication with the polymer or resist layer of the printed circuit wafer.

The invention is directed to a microfluidic system in which conventional printed circuit board materials, such as FR4 (epoxy-glass fiber tissue), FR5, Teflon, and polyimide are used for the supporting substrate of electrodes serving, for example, to manipulate, select, transport and/or detect chemical compositions, biomolecules, complexes of biomolecules, biological cells or parts/fragments of cells, and for the electric connection of the electrodes. Further, the invention is directed to a method for manufacturing hybrid microfluidic chips using conventional printed circuit boards and multilayer techniques for an electrically active manipulation and detection of chemical compositions, biomolecules, micro particles or biological cells.

The use of silicon, glass and plastics as the substrate of microfluidic material layers in which crevices of different depths are provided which form microchannels is already known. The surfaces of these materials can be structured in a well controllable and reproducible manner using (soft) lithographic processes and/or suitable forming methods.

Forming electric connection layers on or in glass, silicon or plastics is possible only with an increased technological effort; this is particularly true when a plurality of electrically conductive layers are to be arranged on top of each other, which may be necessary especially with complex applications to allow for an effective routing of the electric conductor paths.

On the other hand, inexpensive substrates with a plurality of electrically conductive (conductor path) layers are known from conventional circuit board technology. However, the irreversible mechanical connection of such multilayer circuit boards to a microchannel material layer is still difficult.

Thus, it is an object of the invention to provide a method for coupling easy-to-handle, multilayer circuit board substrates with a biocompatible fluidic substrate component, as well as a microfluidic chip thus manufactured.

To achieve this object, the invention provides a method for manufacturing a hybrid microfluidic system equipped with:
a printed circuit board comprising a polymeric support layer (circuit board material), at least one surface of the support layer being provided with an electrically conductive layer including a plurality of electrodes, and said electrically conductive layer is provided with one or more resist or polymer layer(s) based on acryl, epoxy resin, phenolic resin, silicon resin or fluorinated polymer, said layer(s) being adapted to be patterned by photolithography or an electron beam while leaving at least one of the said electrodes exposed, and
one or more microchannel material layer(s) with an outer surface provided with recesses forming said microchannels,
the material layer comprising PDMS (Polydimethylsiloxane, SYLGARD®, DOW Corning), other organic siloxanes, including their polymerization products, silicones, polyacrylates (e.g. PMMA) and/or elastomeres with functional groups containing oxygen and/or nitrogen (e.g. polysulphone, polycarbonate and/or polyacrylonitrile),
the recessed outer surface of the microchannel material layer contacting the photoresist layer of the printed circuit board such that at least one of the said electrodes is aligned with one of said recesses, and
the outer surface of the material layer being fluid-tightly connected with the resistor polymer layer of the printed circuit board.

In an advantageous development of the invention, the photoresist layer comprises the epoxy resin SU-8® (MicroChem Corp.), bisbenzocyclobutene (Cycloten®, DOW) or CYTOP® (Cyclic Transparent Optical Polymer, Asahi Glass Company).

Optionally, the fluid-tight connection between the outer side of the microchannel material layer and the resistor polymer layer may advantageously be assisted by a plasma, preferably an oxygen plasma.

In another advantageous embodiment of the invention, the printed circuit board has at least one of its two sides provided with an electrically conductive multilayer layer structure comprising a plurality of electrically conductive layers electrically insulated from each other, the topmost of these layers comprising the electrode.

Further, the printed circuit board of the present system is advantageously provided with a single or multilayer electrically conductive layer on each of its two sides and has via openings for the electrical interconnection of the electrically conductive layers.

Finally, it may advantageously be provided that the printed circuit board comprises at least one fluid channel for establishing the fluid communication of the microchannels, which fluid channel extends from the circuit board side connected with the microchannel material layer to the other, opposite side thereof.

SU-8® as the photoresist layer and PDMS as the microchannel material layer have turned out to be a particularly advantageous material combination.

The invention especially refers to reconfigurable (i.e. switchable) electrode arrangements on multilayer PCB's (Printed Circuit Boards) provided with one or a plurality of thin polymer layers (e.g. photoresist SU-8®) adapted to be structured through lithographic processes and serving as a substrate for microfluidic systems. The polymer layers act as biocompatible, planarizing and otherwise physical protective and/or separating layers, but also as a coupling substrate to the PDMS fluidic level, and they may additionally serve as a structurable material for forming microchannels in the microfluidic system and as a soldermask for equipping the circuit board material with electronic components. In other words: the fluidic level is not necessarily determined by the microchannel position alone but, in addition, also by corresponding structures in the photoresist layer.

For the first time, the design of hybrid bio-chips on PCB basis, made it possible to combine microfluidic components with a plurality of electric layers. Such bio-chips allow for an online-controlled manipulation of electrically charged molecules and microparticles and for a simultaneous optical monitoring. The latter is the basis for an on-chip integration of biochemical standard processes such as, for example, the hybridizing and amplification of nucleic acids. Thus, the bio-chip based on conventional circuit board technology opens new fields of application in the domains of biomolecular diagnostics and combinatorial chemistry to microreaction technology and evolutionary biotechnology.

Integrated applications on bio-chips in biotechnology are presently limited by time-consuming development cycles for the manufacture of systems specific to an application. By means of digitally pulsed microelectrodes, user-programmable biochips allow for an efficient transport of biomolecules (DNA, proteins, etc.) through microfluidic channels both to on-chip integrated microreactors and to detection sites, the biomolecules being tracked using laser-induced fluorescence detection.

Up to the present, these hybrid bio-chips have been manufactured using high-cost semiconductor-technology manufacturing methods, since the structural dimensions typical of microfluidic applications could be successfully realized with established methods of microsystem technology.

A multitude of Microsystems—primarily manufactured on the basis of silicon, glass or polydimethylsiloxane (PDMS)—mostly having a microfluidic and/or an electrical level, are witnesses to this development. However, the electrokinetic transport of molecules within these fluidic systems requires an increasingly high number of on-chip microelectrode arrangements, since the actuator electrodes on the chip component have to be controlled individually. This latter fact makes routing the required conductor paths on only one electric layer very complex and imposes enormous restrictions on the scalability of the integration.

To avoid this problem, the invention provides that a PCB is substituted for the silicon substrate processed according to semiconductor technology. Thus, a plurality of electrical layers can be realized at low cost, allowing one to effectively contact the microelectrodes. These novel low-cost bio-chips include a microfluidic component, preferably of (transparent) PDMS, and a circuit board, preferably with a plurality of electrical levels for an easy and scalable contacting of the microelectrodes on the upper surface of the electrical layers.

The following variants of embodiments of the present hybrid PCB chips are possible, for example:
1. A multilayer PCB substrate with one or a plurality of via(s) for contacting the microchannel material layer in PDMS or the above mentioned materials on the upper surface of the chip.
2. A multilayer PCB substrate with one or a plurality of via(s) for contacting the microchannel material layers in PDMS or the above mentioned materials on the upper and lower surfaces of the chip.
3. A multilayer PCB substrate with one or a plurality of via(s) and one or a plurality of microchannel material layers in PDMA or the above mentioned materials and a polymer layer (e.g. SU-8) on the upper surface of the chip, having microchannels therein.
4. A multilayer PCB substrate with vias and two microchannel material layers in PDMS, for example, and a microchannel structure in SU-8, for example, on the upper surface of the chip.
5. A multilayer PCB substrate with vias and two microchannel material layers in PDMS, for example, and two microchannel structures in SU-8, for example, on the upper and lower surfaces of the chip.

The manufacturing of the present hybrid bio-chip is, for example, a combination of known structuring and moulding methods of microsystem technology.

Following conventional methods, symmetrically designed four-layer circuit boards were manufactured from the substrate polyimide as a biocompatible circuit board base material, the plates including one or a plurality of chips of 2.8 cm×3.2 cm in size. This format was chosen to be able to employ established lithographic processes analogous to the established 4″ wafer technology. The interlayer connection (vias) for the connection of the individual electric layers were realized both as mechanical and laser bored holes. The copper conductor paths (dimensions: height 17.5 μm, width 100 μm) and the electrodes were covered with a chemically inert layer of gold to guarantee a good compatibility with biochemical solutions. This was followed by coating and lithographically structuring the polymer layer which, on the one hand, serves to completely planarize the PCB surface, insulates the conductor paths from the fluidic channels and, on the other hand, defines the contact of the electrodes with the microfluidic channels by selective opening (structural dimensions: 60 μm×60 μm). The polymer used was SU-8 (microresist technologies, Berlin) which lends itself to photolithographic structuring with an excellent aspect ratio and which, last but not least, is superbly suited for (bio) MEMS applications because of its biocompatible properties.

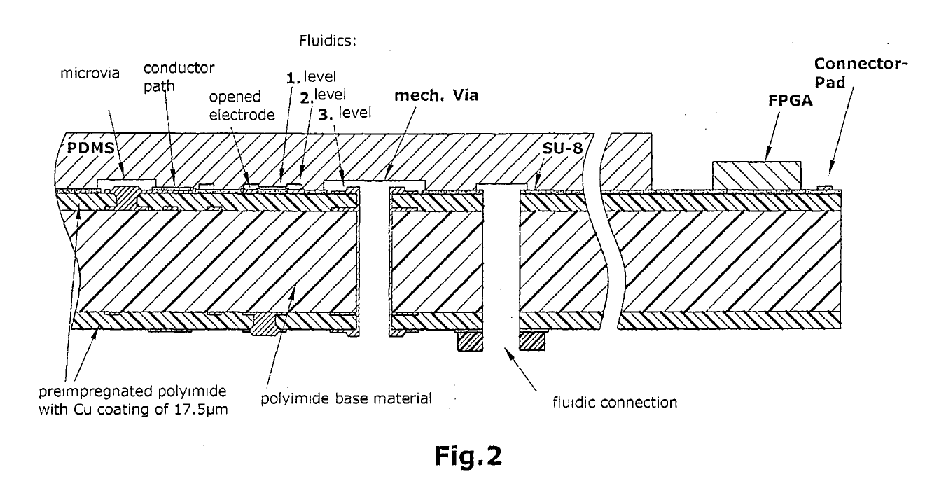

The microfluidic layers are fabricated by means of microreplication of a previously made master. To do this, three structure levels are made from SU-8 on a silicon substrate, from which three respective discrete channel depths result after replication in PDMS (Sylgard 184, Dow Corning). As illustrated in FIG. 2, a plasma-assisted bonding method is then used to bond the microfluidics realized in PDMS permanently and irreversibly to the polymer layer previously applied on the electrode layer. After the chips had then been individualized, they were equipped with a programmable logic chip (e.g. FPGA, CPLD, μC) using the standard reflow technique, the logic chip serving as an interface to establish the communication with the external control computer and performing the digital electric control of the actor electrodes.

The essential novel aspects of the invention can be summarized in key points as follows:

Concept

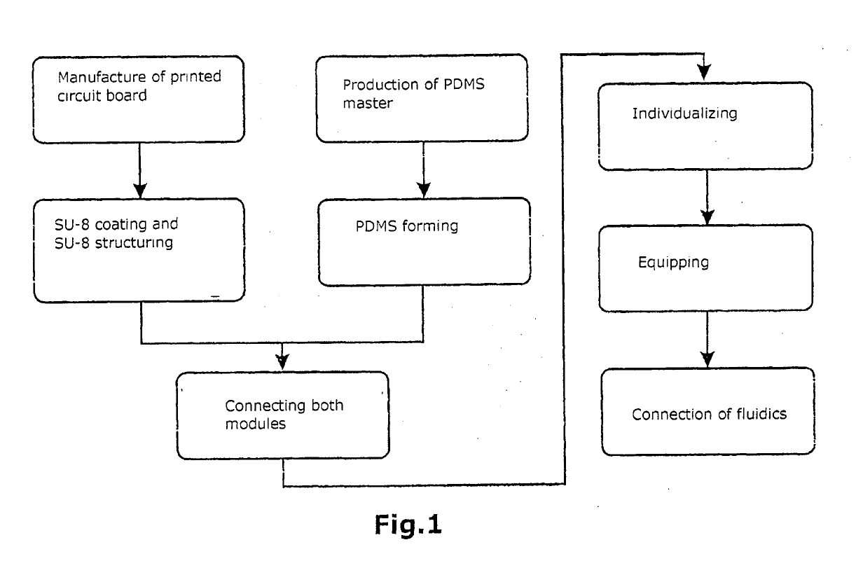

replacing the standard silicon technology by printed circuit boards as the base material for microfluidic applications,
resulting in:
   cost-effective manufacture of electrically active bio-chips (see FIG. 1),
   simplified routing of highly integrated circuits due to multilayer PCB's,
   additional fluidic levels due to an introduced, lithographically structurable polymer layer.
      Integral Components (see FIG. 2)
multilayer printed circuit board as base material (in 100 μm design in the present case),
lithographically structurable polymer coating (here: SU-8),
fluid material layer based on organosiloxanes as well as their polymerization products, silicones, polyacrylates (such as PMMA) and/or elastomers with oxygen- and/or nitrogen-containing functional groups (e.g. polysulphone, polyimide, polycarbonate and/or polyacrylonitrile (here: PDMS)),
programmable logic chip for controlling the electrodes on the chip (e.g. FPGA, CPLD, μC),
connector pad (for external voltage supply),
fluidic connection (for filling the microchannels.
   Object of the Printed Circuit Board
serves as base material (here: manufactured from polyimide composite material),
cost-effective standard production allows for a plurality of electric levels; individual contacting of the electrodes with little routing effort,
topmost layer (electrode) makes contact with the fluidic,
acts as fluidic via for external fluidic connection.
   Objects of the Polymer Layer(s)
planarizing of the printed circuit board surface,
allowing a structural size of the electrodes that is independent of the board design,
insulating the conductor paths from the fluid channels,
allowing a homogeneous bonding behavior of the PDMS with respect to the board material,
serving as a soldermask during further processing,
serving as physical protection and/or separating layers for other purposes.
   Objects of the Fluid Material Layer (PDMS)
production by negative replication method (soft lithography) using a master,
is biocompatible,
may itself include a plurality of fluidic levels,
has excellent optical properties for online monitoring.
   Objects of Programmable Logic Chips (e.g. FPGA, CPLD, μC)
controlling the electrodes (e.g. for the electrokinetic transport of biomolecules in the microfluidic channels),
serves as the interface to the external computer connected via the electric plug-in connector.
   Summary of the Essential Aspects of the Invention
the printed circuit board as the base material for the first time allows one to integrate a plurality of electric layers on hybrid biochips,
simple routing of complex circuits with an almost arbitrary scalability,
by virtue of the polymer layer adapted to the application, a vertical integration of microfluidic components and electric layers is possible on a printed circuit board base.

1. A microfluidic system comprising:
a printed circuit board comprising a polymer support layer (circuit board material), at least one surface of the support layer being provided with an electrically conductive layer including a plurality of electrodes, and the electrically conductive layer is provided with one or more resistor polymer layer(s) based on acryl, epoxy resin, phenolic resin, silicon resin or fluorinated polymer, said layer(s) being adapted to be patterned by photolithography or an electron beam while leaving at least one of said electrodes exposed, and
one or more microchannel material layer(s) with an outer surface provided with recesses forming microchannels,
the material layer comprising PDMS (Polydimethylsiloxane), other organic siloxanes, including their polymerization products, silicones, polyacrylates (e.g. PMMA) and/or elastomeres with functional groups containing oxygen and/or nitrogen (e.g. polysulphone, polycarbonate and/or polyacrylonitrile),
the recessed outer surface of the microchannel material layer contacting the photoresist layer of the printed circuit board such that at least one of the electrodes is aligned with one of the recesses, and
the outer surface of the material layer being fluid-tightly connected with the resistor polymer layer of the printed circuit board.

2. The microfluidic system of claim 1, wherein the photoresist layer comprises SU-8 epoxy resin, bisbenzocyclobutene or cyclic transparent optical polymer.

3. The microfluidic system of claim 1, wherein a forming of a fluid-tight connection between the outer surface of the microchannel material layer and the resistor polymer layer is assisted by plasma treatment.

4. The microfluidic system of claim 1, wherein the printed circuit board has at least one of its two sides provided with an electrically conductive multilayer layer structure comprising a plurality of electrically conductive layers electrically insulated from each other, the topmost of these layers comprising the electrode.

5. The microfluidic system of claim 1, wherein the printed circuit board is advantageously provided with a single or multilayer electrically conductive layer on each of its two sides and has via openings for the electrical connection of the electrically conductive layers.

6. The microfluidic system of claim 1, wherein the printed circuit board comprises at least one fluid channel for establishing the fluid communication of the microchannels, which fluid channel extends from the circuit board side connected with the microchannel material layer to the other, opposite side thereof.

7. The microfluidic system of claim 1, wherein the recesses forming the microchannels are formed in the polymeric support layer or in at least one of the polymeric support layers, the recesses preferably being formed by lithographic structuring.

8. A method for manufacturing a microfluidic system, the method comprising the following steps:
providing a printed circuit board comprising a polymeric support layer (circuit board material), at least one surface of the support layer being provided with an electrically conductive layer including a plurality of electrodes,
depositing one or more resistor polymer layer(s) based on acryl, epoxy resin, phenolic resin, silicon resin or fluorinated polymer,
structuring said resist or polymer layer(s) by photolithography or an electron beam to produce electrodes exposed in the resist or polymer layer(s),
providing one or more microchannel material layer(s) with a respective outer surface provided with recesses forming microchannels, and
bonding the outer surface of each microchannel material layer with one of the resist or polymer layers on the printed circuit board for the fluid-tight connection of both, at least two electrodes being aligned with a respective one of the recesses in the microchannel material layer(s).

9. The microfluidic system of claim 2, wherein a forming of a fluid-tight connection between the outer surface of the microchannel material layer and the resistor polymer layer is assisted by plasma treatment.

10. The microfluidic system of claim 2, wherein the printed circuit board has at least one of its two sides provided with an electrically conductive multilayer layer structure comprising a plurality of electrically conductive layers electrically insulated from each other, the topmost of these layers comprising the electrode.

11. The microfluidic system of claim 3, wherein the printed circuit board has at least one of its two sides provided with an electrically conductive multilayer layer structure comprising a plurality of electrically conductive layers electrically insulated from each other, the topmost of these layers comprising the electrode.

12. The microfluidic system of claim 2, wherein the printed circuit board is advantageously provided with a single or multilayer electrically conductive layer on each of its two sides and has via openings for the electrical connection of the electrically conductive layers.

13. The microfluidic system of claim 3, wherein the printed circuit board is advantageously provided with a single or multilayer electrically conductive layer on each of its two sides and has via openings for the electrical connection of the electrically conductive layers.

14. The microfluidic system of claim 4, wherein the printed circuit board is advantageously provided with a single or multilayer electrically conductive layer on each of its two sides and has via openings for the electrical connection of the electrically conductive layers.

15. The microfluidic system of claim 2, wherein the printed circuit board comprises at least one fluid channel for establishing the fluid communication of the microchannels, which fluid channel extends from the circuit board side connected with the microchannel material layer to the other, opposite side thereof.

16. The microfluidic system of claim 3, wherein the printed circuit board comprises at least one fluid channel for establishing the fluid communication of the microchannels, which fluid channel extends from the circuit board side connected with the microchannel material layer to the other, opposite side thereof.

17. The microfluidic system of claim 4, wherein the printed circuit board comprises at least one fluid channel for establishing the fluid communication of the microchannels, which fluid channel extends from the circuit board side connected with the microchannel material layer to the other, opposite side thereof.

18. The microfluidic system of claim 5, wherein the printed circuit board comprises at least one fluid channel for establishing the fluid communication of the microchannels, which fluid channel extends from the circuit board side connected with the microchannel material layer to the other, opposite side thereof.

19. The microfluidic system of claim 2, wherein the recesses forming the microchannels are formed in the polymeric support layer or in at least one of the polymeric support layers, the recesses preferably being formed by lithographic structuring.

20. The microfluidic system of claim 3, wherein the recesses forming the microchannels are formed in the polymeric support layer or in at least one of the polymeric support layers, the recesses preferably being formed by lithographic structuring.

21. The microfluidic system of claim 4, wherein the recesses forming the microchannels are formed in the polymeric support layer or in at least one of the polymeric support layers, the recesses preferably being formed by lithographic structuring.

22. The microfluidic system of claim 5, wherein the recesses forming the microchannels are formed in the polymeric support layer or in at least one of the polymeric support layers, the recesses preferably being formed by lithographic structuring.

23. The microfluidic system of claim 6, wherein the recesses forming the microchannels are formed in the polymeric support layer or in at least one of the polymeric support layers, the recesses preferably being formed by lithographic structuring.
